(19) United States
(12) Patent Application Publication
(10) Pub. No.: US 2024/0413053 A1
(43) Pub. Date: Dec. 12, 2024

(54) HEAT RADIATION DEVICES

(71) Applicant: SAMSUNG ELECTRONICS CO., LTD., Suwon-si (KR)

(72) Inventors: Youngjoon Koh, Suwon-si (KR); Jae Choon Kim, Suwon-si (KR)

(21) Appl. No.: 18/410,761

(22) Filed: Jan. 11, 2024

(30) Foreign Application Priority Data
Jun. 12, 2023 (KR) 10-2023-0074689

(51) Int. Cl. H01L 23/427; H01L 23/00

(52) U.S. Cl. CPC H01L 23/427; H01L 24/32; H01L 25/0655; H01L 2224/32245

(57) ABSTRACT

Disclosed are heat radiation devices and semiconductor apparatuses including the same. The semiconductor apparatus comprises a substrate, a plurality of semiconductor devices on the substrate and arranged in a first direction as a horizontal direction, and a heat radiation device on the plurality of semiconductor devices. The heat radiation device provides a plurality of vapor chambers. The plurality of vapor chambers are spaced apart from each other in the first direction and are not connected to each other.

### CROSS-REFERENCE TO RELATED APPLICATION

This U.S. nonprovisional application claims priority under 35 U.S.C § 119 to Korean Patent Application No. 10-2023-0074689 filed on Jun. 12, 2023, in the Korean Intellectual Property Office, the disclosure of which is hereby incorporated by reference in its entirety.

### TECHNICAL FIELD

The present disclosure relates to heat radiation devices.

### BACKGROUND

A semiconductor package is provided to implement an integrated circuit chip to qualify for use in electronic products. The semiconductor package may be fabricated by mounting a semiconductor chip on a substrate such as a printed circuit board (PCB). A single semiconductor package may have a plurality of mounted semiconductor chips. A plurality of semiconductor chips may have various functions. The plurality of semiconductor chips may be stacked on one substrate. Heat may be generated from the plurality of semiconductor chips stacked on the substrate.

### SUMMARY

Some implementations according to the present disclosure relate to a heat radiation device capable of effectively radiating heat generated from a semiconductor device and to a semiconductor apparatus including the same.

Some implementations according to the present disclosure relate to a heat radiation device capable of preventing heat transfer among a plurality of semiconductor devices and to a semiconductor apparatus including the same.

Some implementations according to the present disclosure relate to a heat radiation device capable of securing mechanical stability and to a semiconductor apparatus including the same.

Implementations are not limited to those mentioned above, and other implementations will be clearly understood to those skilled in the art from the following description and from the drawings.

In some implementations, a semiconductor apparatus comprises: a substrate; a plurality of semiconductor devices on the substrate and arranged in a first direction as a horizontal direction; and a heat radiation device on the plurality of semiconductor devices. The heat radiation device may provide a plurality of vapor chambers. The plurality of vapor chambers may be spaced apart from each other in the first direction and are not connected to each other.

In some implementations, a semiconductor apparatus comprises: a substrate; a plurality of semiconductor devices on the substrate; and a heat radiation device on the plurality of semiconductor devices. The plurality of semiconductor devices may be spaced apart from each other in a first direction as a horizontal direction. The heat radiation device may provide: a plurality of vapor chambers arranged in the first direction; and a heat pipe channel between two neighboring ones of the plurality of vapor chambers, the heat pipe channel extending in a second direction as a horizontal direction that intersects the first direction.

In some implementations, a heat radiation device comprises: a radiation plate; and a support structure coupled to the radiation plate. The radiation plate may provide: a first vapor chamber surrounded by the radiation plate; and a second vapor chamber surrounded by the radiation plate and spaced apart in a horizontal direction from the first vapor chamber. The support structure may include: a support pillar that extends from a first floor surface of the radiation plate to a first ceiling surface of the radiation plate, the first floor surface and the first ceiling surface defining the first vapor chamber; and a plurality of support plates that extend form the first floor surface to the first ceiling surface and are coupled to the support pillar. The plurality of support plates may be spaced apart from each other in a circumferential direction around the support pillar.

Details of other examples of implementations are included in the description and drawings.

### BRIEF DESCRIPTION OF THE DRAWINGS

FIG. 1 illustrates a cross-sectional view showing an example of a semiconductor apparatus according to some implementations of the present disclosure.

FIG. 2 illustrates an exploded cross-sectional view showing an example of a semiconductor apparatus according to some implementations of the present disclosure.

FIG. 3 illustrates an enlarged cross-sectional view showing section X of FIG. 1.

FIG. 4 illustrates a plan view showing an example of a substrate and a semiconductor device of a semiconductor apparatus according to some implementations of the present disclosure.

FIG. 5 illustrates a plan view showing an example of a heat radiation device of a semiconductor apparatus according to some implementations of the present disclosure.

FIG. 6 illustrates an enlarged plan view showing section Y depicted in FIG. 5.

FIGS. 7 and 8 illustrate cross-sectional and plan views, respectively, showing a use state of a semiconductor apparatus according to some implementations of the present disclosure.

FIG. 9 is a graph illustrating an effect of thermal radiation by a semiconductor apparatus according to some implementations of the present disclosure.

FIG. 10 illustrates a cross-sectional view showing an example of a semiconductor apparatus according to some implementations of the present disclosure.

FIG. 11 illustrates an enlarged cross-sectional view showing section X′ of FIG. 10.

FIG. 12 illustrates a plan view showing an example of a heat radiation device of a semiconductor apparatus according to some implementations of the present disclosure.

FIG. 13 illustrates an enlarged plan view showing section Y′ of FIG. 12.

### DETAILED DESCRIPTION

The following will now describe some implementations of the present disclosure with reference to the accompanying drawings. Like reference numerals indicate like components throughout the description.

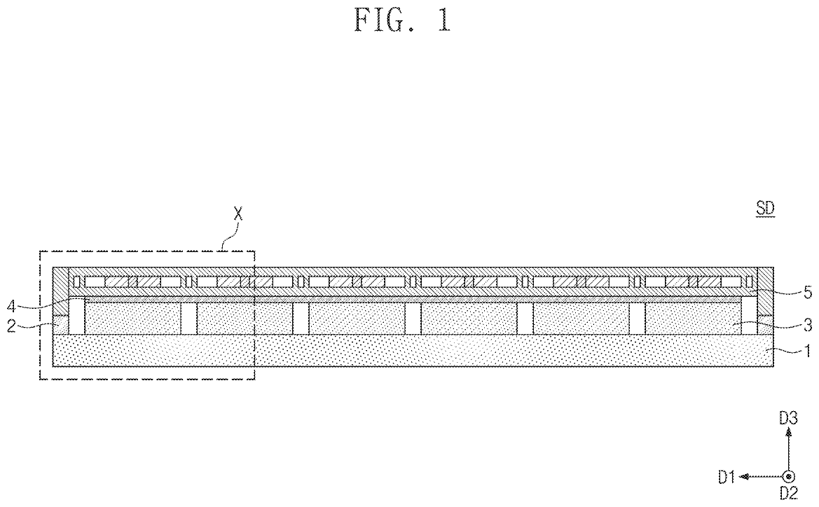

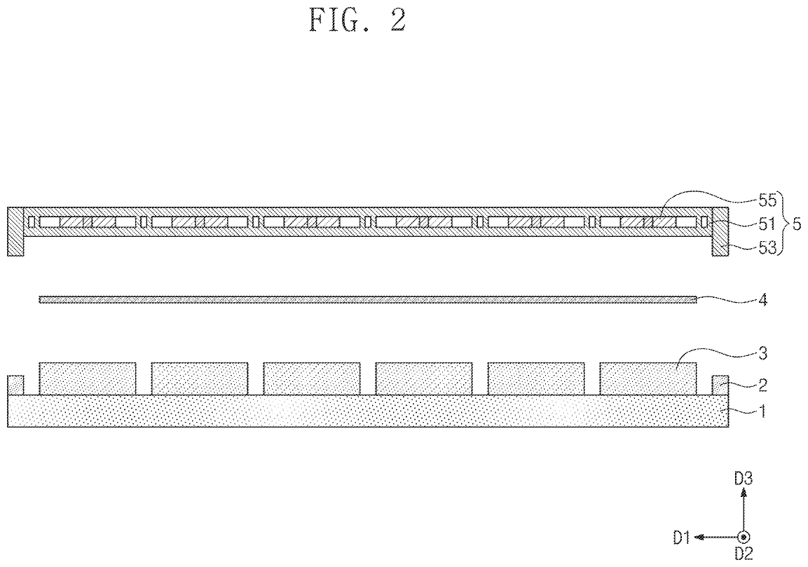

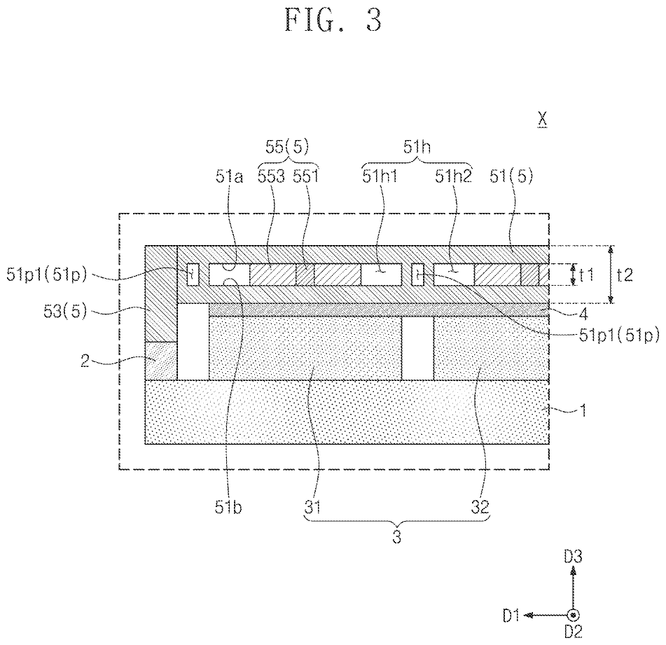

FIG. 1 illustrates a cross-sectional view showing a semiconductor apparatus according to some implementations of the present disclosure. FIG. 2 illustrates an exploded cross-sectional view showing a semiconductor apparatus according to some implementations of the present disclosure. FIG. 3 illustrates an enlarged cross-sectional view showing section X of FIG. 1.

In this description, symbol D1 indicates a first direction, symbol D2 indicates a second direction that intersects the first direction D1, and symbol D3 indicates a third direction that intersects each of the first direction D1 and the second direction D2. Each of the first and second directions D1 and D2 may be called a horizontal direction. The third direction D3 may be called a vertical direction. D1, D2, and D3 may be orthogonal to one another.

Referring to FIGS. 1 to 3, a semiconductor apparatus SD is provided. The semiconductor apparatus SD may be an apparatus in which a plurality of semiconductor chips are mounted. For example, the semiconductor apparatus SD may be configured such that a plurality of semiconductor packages are mounted on one board. In some implementations, the semiconductor apparatus SD is configured such that a plurality of semiconductor chips are mounted on one printed circuit board (PCB). The semiconductor apparatus SD includes a substrate 1, a semiconductor device 3, a heat radiation device 5, an adhesion layer 4, and an edge adhesion layer 2.

In some implementations, the substrate 1 supports the semiconductor device 3. The substrate 1 may have a plate shape having a normal line (normal to an extending surface of the plate) parallel to the third direction D3. The substrate 1 may have, for example, a board shape. In detail, the substrate 1 may include a printed circuit board. The present disclosure, however, is not limited thereto, and the substrate 1 may have any other suitable shape.

The semiconductor device 3 may be disposed on the substrate 1. The semiconductor device 3 may be one semiconductor chip. For example, the semiconductor device 3 may include a memory chip or a logic chip. Alternatively, the semiconductor device 3 may include a semiconductor package including a semiconductor chip. The semiconductor device 3 may be provided in plural. For example, there may be provided a first semiconductor device 31 and a second semiconductor device 32, labeled in FIG. 3. The present disclosure, however, is not limited thereto, and the number of the semiconductor devices 3 may be different from one, two, three, or a different number. The plurality of semiconductor devices 3 may be arranged in a horizontal direction. For example, the plurality of semiconductor devices 3 may be disposed spaced apart from each other in a horizontal direction, e.g., in an array. In the example of FIGS. 1-3, the plurality of semiconductor devices 3 are disposed spaced apart from each other in the first direction D1. Unless otherwise specially noted, a semiconductor device 3 will be discussed below, with the semiconductor device 3 understood as encompassing, in some implementations, multiple semiconductor devices.

The heat radiation device 5 may be positioned on the semiconductor device 3, e.g., in contact with the semiconductor device 3 or with one or more intervening elements, such as adhesion layer 4. The heat radiation device 5 is arranged to outwardly discharge heat generated from the semiconductor device 3. In some implementations, as shown in FIG. 3, the heat radiation device 5 includes a vapor chamber 51h and a heat pipe channel 51p.

Referring to FIG. 3, the vapor chamber 51h may be positioned on the semiconductor device 3, e.g., vertically aligned with the semiconductor device 3. The vapor chamber 51h can include a space surrounded by the heat radiation device 5. The heat radiation device 5 may define the vapor chamber 51h. For example, the vapor chamber 51h may be defined by a first ceiling surface 51a and a first floor surface 51b of the vapor chamber 51h, where, for example, the first ceiling surface 51a and the first floor surface 51b may be surfaces of the head radiation device 5. The vapor chamber 51h may be isolated from an external space. Therefore, a fluid in the vapor chamber 51h may not be discharged to the external space. A vapor may be present in the vapor chamber 51h. The vapor present in the vapor chamber 51h may include, for example, water (H₂O), but is not limited thereto.

A first thickness t1 may be defined to indicate a thickness of the vapor chamber 51h. The first thickness t1 may be a length in the third direction D3. The first thickness t1 may be a distance between the first floor surface 51b and the first ceiling surface 51a. The first thickness t1 may range from about 0.3 mm to about 1.5 mm. For example, the first thickness t1 may range from about 0.5 mm to about 1.0 mm. The first thickness t1 may be constant across a breadth of the vapor chamber 51h in one or both of the D1 and D2 directions. For example, the vapor chamber 51h may have a constant thickness. For example, the first thickness t1 may be constant in the first direction D1.

The vapor chamber 51h may be included in plural. For example, there may be provided a first vapor chamber 51h1 and a second vapor chamber 51h2, as shown in FIG. 3. When viewed in a plan view, the first vapor chamber 51h1 may overlap the first semiconductor device 31 (e.g., may be partially or entirely aligned with the first semiconductor device 31 in the vertical direction D3). For example, the first vapor chamber 51h1 may be positioned on the first semiconductor device 31. When viewed in a plan view, the second vapor chamber 51h2 may overlap the second semiconductor device 32 (e.g., may be partially or entirely aligned with the second semiconductor device 32 in the vertical direction D3). For example, the second vapor chamber 51h2 may be positioned on the second semiconductor device 32. When viewed in a plan view, the second vapor chamber 51h2 may not overlap the first semiconductor device 31. When viewed in a plan view, the second vapor chamber 51h2 may not overlap the second semiconductor device 32. A width in the first direction D1 of the first vapor chamber 51h1 may be substantially the same as a width in the first direction D1 of the first semiconductor device 31. The present disclosure, however, is not limited thereto.

Although two vapor chambers are described by way of example, no limitation is imposed on the number of the one or more vapor chambers 51h. When a plurality of vapor chambers 51h are included, the plurality of vapor chambers 51h may be arranged in a horizontal direction. For example, the plurality of vapor chambers 51h may be arranged spaced apart from each other in the first direction D1. The plurality of vapor chambers 51h may be disconnected from one another, e.g., may not exchange vapor. A detailed description thereof will be further discussed below. Unless otherwise specially noted, a single vapor chamber 51h will be discussed below, with the understanding that multiple vapor chambers 51h are included in some implementations.

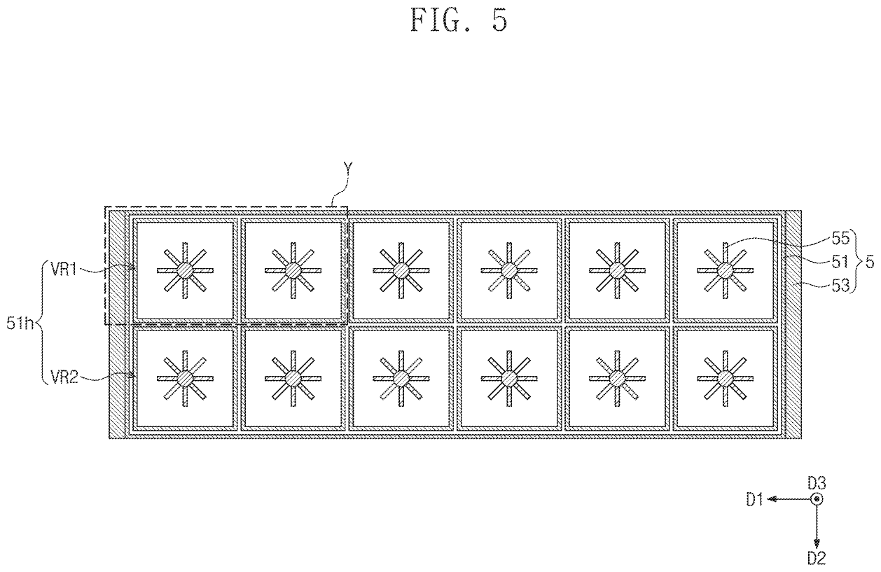

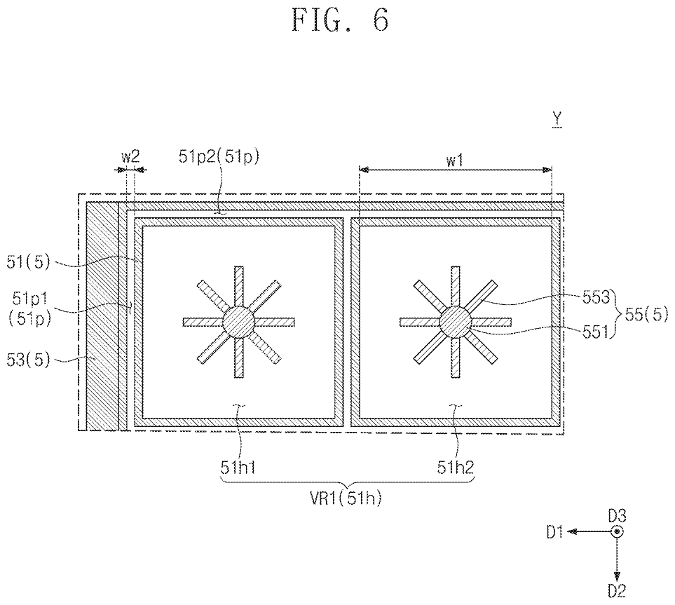

The heat pipe channel 51p may include a first heat pipe channel 51p1. The first heat pipe channel 51p1 may be positioned between two neighboring ones of the plurality of vapor chambers 51h, e.g., between 51h1 and 51h2, and/or adjacent to an edge vapor chamber, e.g., between an edge vapor chamber and a support member as shown in FIG. 3. The first heat pipe channel 51p1 may be disconnected from the vapor chamber 51h, e.g., may not exchange vapor with the vapor chamber 51h. The first heat pipe channel 51p1 may be separated from the vapor chamber 51h. The first heat pipe channel 51p1 may extend in a horizontal direction. For example, the first heat pipe channel 51p1 may extend in the second direction D2. The heat pipe channel 51p is further discussed in detail below, e.g., in reference to FIGS. 5-6.

As shown in FIG. 3, in some implementations, the heat radiation device 5 includes a radiation plate 51, a support member 53, and a support structure 55.

The radiation plate 51 may be positioned on the semiconductor device 3. The radiation plate 51 may define the vapor chamber 51h and the heat pipe channel 51p. The vapor chamber 51h and a heat pipe channel 51p may be provided within the radiation plate 51, e.g., extending between internal surfaces of the radiation plate 51. The first floor surface 51b and the first ceiling surface 51a may each be a surface of the radiation plate 51. A second thickness t2 may be defined to indicate a thickness of the radiation plate 51. The second thickness t2 may be a length in the third direction D3 of the radiation plate 51. The second thickness may range from about 3 mm to about 5 mm, but the present disclosure is not limited thereto. The radiation plate 51 may include, for example, metal.

The support member 53 may downwardly extend from an edge of the radiation plate 51. For example, a bottom surface of the support member 53 may be located at a vertical level lower than that of a bottom surface of the radiation plate 51. The support member 53 may be coupled onto (e.g., attached to) the substrate 1. For example, the support member 53 may be fixed through the edge adhesion layer 2 onto the substrate 1. In some implementations, the support member 53 and the radiation plate 51 are integrally formed to constitute a single unitary piece. The support member 53 may have a tetragonal frame shape. The present disclosure, however, is not limited thereto, and the support member 53 may have a ring shape.

The support structure 55 may be coupled to the radiation plate 51. For example, the support structure 55 may be positioned within the vapor chamber 51h. The support structure 55 may support the radiation plate 51. The support structure 55 may include a support pillar 551 and a support plate 553. A detailed description thereof will be further discussed below, e.g., in relation to FIGS. 5-6.

The adhesion layer 4 may be positioned between the semiconductor device 3 and the heat radiation device 5. For example, the adhesion layer 4 may be positioned between (e.g., in contact with each of) the semiconductor device 3 and the radiation plate 51. The adhesion layer 4 may include, for example, a thermal interface material (TIM). The adhesion layer 4 may contact a top surface of the semiconductor device 3. For example, the adhesion layer 4 may contact an entirety of the top surface of a corresponding one of the plurality of semiconductor devices 3. The heat radiation device 5 may be fixed through the adhesion layer 4 onto the semiconductor device 3. Heat generated from the semiconductor device 3 may migrate through the adhesion layer 4 to the heat radiation device 5.

The edge adhesion layer 2 may be provided on the substrate 1. For example, the edge adhesion layer 2 may be positioned at an edge of the substrate 1. A top surface of the edge adhesion layer 2 may contact the heat radiation device 5. For example, the top surface of the edge adhesion layer 2 may contact the bottom surface of the support member 53. The heat radiation device 5 may be fixed through the edge adhesion layer 2 onto the substrate 1.

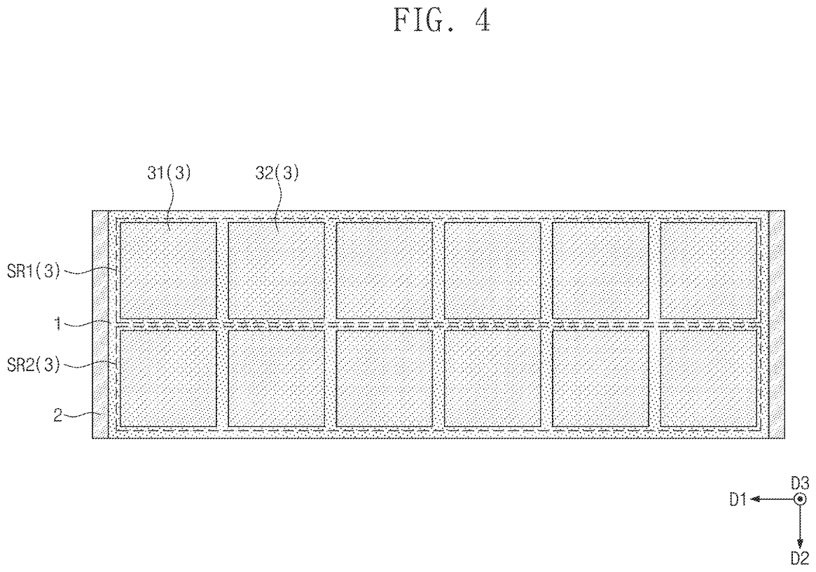

FIG. 4 illustrates a plan view showing a substrate and a semiconductor device of a semiconductor apparatus according to some implementations of the present disclosure.

Referring to FIG. 4, there is provided a first device row SR1 and a second device row SR2.

The first device row SR1 may include a plurality of semiconductor devices 3 arranged in the first direction D1. For example, the first semiconductor device 31 and the second semiconductor device 32 may be a portion of the first device row SR1.

The second device row SR2 may include a plurality of semiconductor devices 3 arranged in the first direction D1. The second device row SR2 may be disposed spaced apart in the second direction D2 from the first device row SR1.

FIG. 5 illustrates a plan view showing a heat radiation device of a semiconductor apparatus according to some implementations of the present disclosure. FIG. 6 illustrates an enlarged plan view showing section Y depicted in FIG. 5.

Referring to FIGS. 5 and 6, a first row VR1 and a second row VR2 are provided. The first row VR1 and the second row VR2 may be a portion of the plurality of vapor chambers 51h.

The first row VR1 may include a plurality of vapor chambers 51h arranged in the first direction D1. For example, the first vapor chamber 51h1 and the second vapor chamber 51h2 may be a portion of the first row VR1.

The second row VR2 may include a plurality of vapor chambers 51h arranged in the first direction D1. The second row VR2 may be disposed spaced apart in the second direction D2 from the first row VR1.

The heat pipe channel 51p may further include a second heat pipe channel 51p2. The second heat pipe channel 51p2 may be positioned between the first row VR1 and the second row VR2, and/or adjacent to an edge row, e.g., extending along the first row VR1 opposite the second row VR2, as shown in FIG. 6. The second heat pipe channel 51p2 may extend in the first direction D1. The second heat pipe channel 51p2 may be connected to the first heat pipe channel 51p1, e.g., may form a continuous channel.

A first width w1 may be defined to indicate a width in the first direction D1 of the vapor chamber 51h. A second width w2 may be defined to indicate a width in the first direction D1 of the first heat pipe channel 51p1. The first width w1 may be greater than the second width w2.

A fluid may be provided in the heat pipe channel 51p. For example, a vapor may be provided in the heat pipe channel 51p. The vapor provided in the heat pipe channel 51p may include, for example, water (H₂O).

The support structure 55 may include a support pillar 551 and a support plate 553.

The support pillar 551 may be positioned in the vapor chamber 51h. For example, the support pillar 551 may extend from the first floor surface (see 51b of FIG. 3) to the first ceiling surface (see 51a of FIG. 3). The support pillar 551 may support the first ceiling surface 51a. The support pillar 551 may include metal, but the present disclosure is not limited thereto. The support pillar 551 may be positioned at a center of the vapor chamber 51h, but the present disclosure is not limited thereto.

The support plate 553 may be positioned in the vapor chamber 51h. The support plate 553 may extend from the first floor surface (see 51b of FIG. 3) to the first ceiling surface (see 51a of FIG. 3). The support plate 553 may support the first ceiling surface 51a. The support plate 553 may be coupled to the support pillar 551. The support plate 553 may extend in a radial direction from the support pillar 551. The support plate 553 may include metal, but the present disclosure is not limited thereto. The support plate 553 may be provided in plural. The plurality of support plates 553 may be arranged spaced apart from each other in a circumferential direction around the support pillar 551. A single support plate 553 will be discussed below.

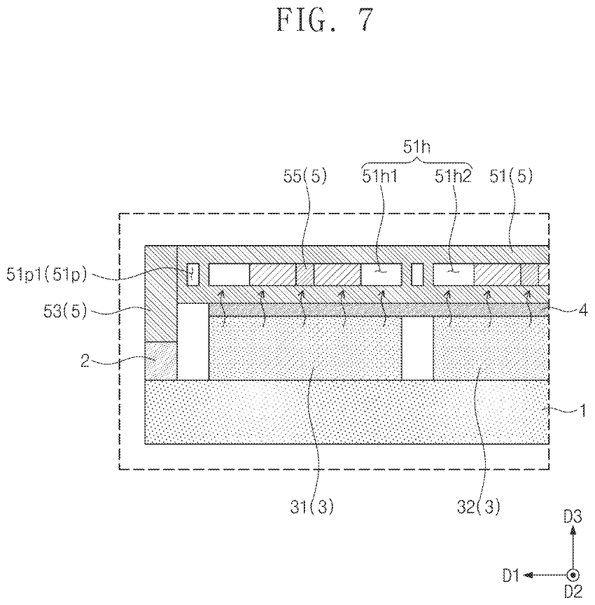

FIGS. 7 and 8 illustrate cross-sectional and plan views showing a use state of a semiconductor apparatus (e.g., the apparatus of any of FIGS. 1-6) according to some implementations of the present disclosure.

Referring to FIGS. 7 and 8, heat may be generated during an operation of the semiconductor device 3. The heat generated from the semiconductor device 3 may be transferred to the surrounding environment. For example, the heat generated from the semiconductor device 3 may be transferred to the vapor chamber 51h. In detail, the heat generated from the first semiconductor device 31 may be transferred through the adhesion layer 4 to the first vapor chamber 51h1. The heat transferred to the first vapor chamber 51h1 may move the vapor in the first vapor chamber 51h1. For example, the vapor within the first vapor chamber 51h1 may migrate in various directions. Therefore, the heat may be uniformly dispersed. When a plurality of support plates 553 are disposed spaced apart from each other in a circumferential direction, the vapor may migrate in a radial direction between the plurality of support plates 553, which may result in dispersion of heat. The heat in the vapor chamber 51h may be transferred to the heat pipe channel 51p. The heat transferred to the heat pipe channel 51p may move in the first direction D1 and/or the second direction D2. There may thus be a reduction in heat transfer between the vapor chambers 51h. For example, heat generated from the first vapor chamber 51h1 may be prevented from being transferred to the second vapor chamber 51h2, or heat transfer from the first vapor chamber 51h1 to the second vapor chamber 51h2 may be reduced.

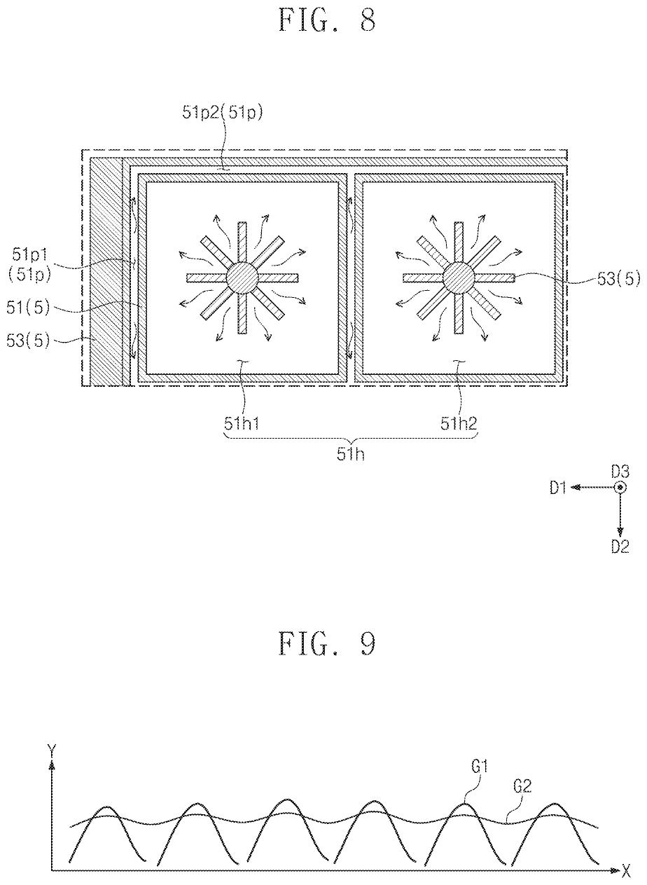

FIG. 9 illustrates a graph showing an effect of thermal radiation by a semiconductor apparatus according to some implementations of the present disclosure.

Referring to FIG. 9, a horizontal axis (X) may denote the first direction D1. A vertical axis (Y) may denote a temperature. Symbol G1 may express a temperature distribution due to heat generated from a plurality of semiconductor devices. Symbol G2 may express a temperature distribution due to heat dispersed by a plurality of vapor chambers (see 51h of FIG. 8). Referring to G1 and G2 in FIG. 9, heat generated from a plurality of semiconductor devices may be dispersed by a plurality of vapor chambers. Therefore, a maximum temperature may decrease.

According to a heat radiation device and a semiconductor apparatus in accordance with some implementations of the present disclosure, there may be provided a plurality of vapor chambers that are separated from each other. There may be a reduction in heat transfer between the vapor chambers. Therefore, heat generated from one of a plurality of semiconductor chips may be prevented from being transferred to a neighboring semiconductor chip of the plurality of semiconductor chips. Accordingly, the heat generated from the plurality of semiconductor chips may be effectively discharged. Moreover, a maximum temperature may decrease.

According to a heat radiation device and a semiconductor apparatus in accordance with some implementations of the present disclosure, a support pillar and a support plate may be used to support a radiation plate. It may therefore be possible to secure mechanical stability of a heat radiation device. For example, it may be possible to prevent the radiation plate from thermally induced warpage.

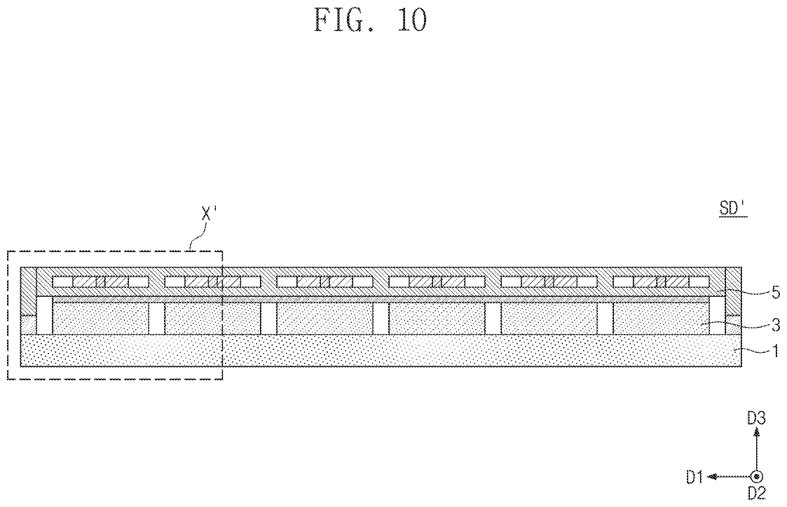

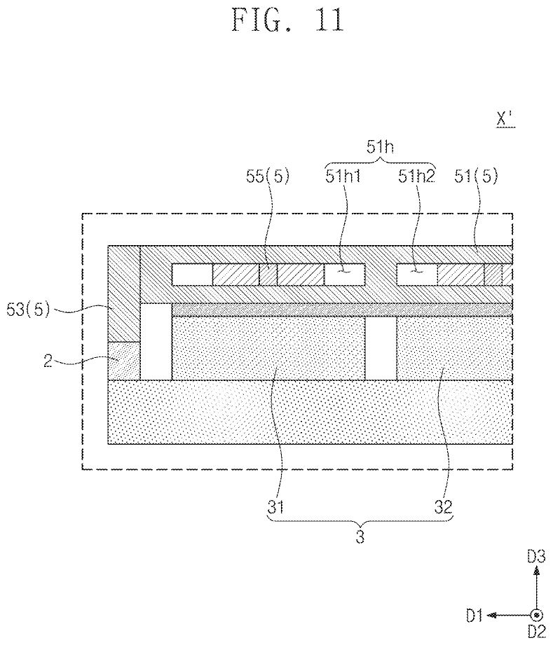

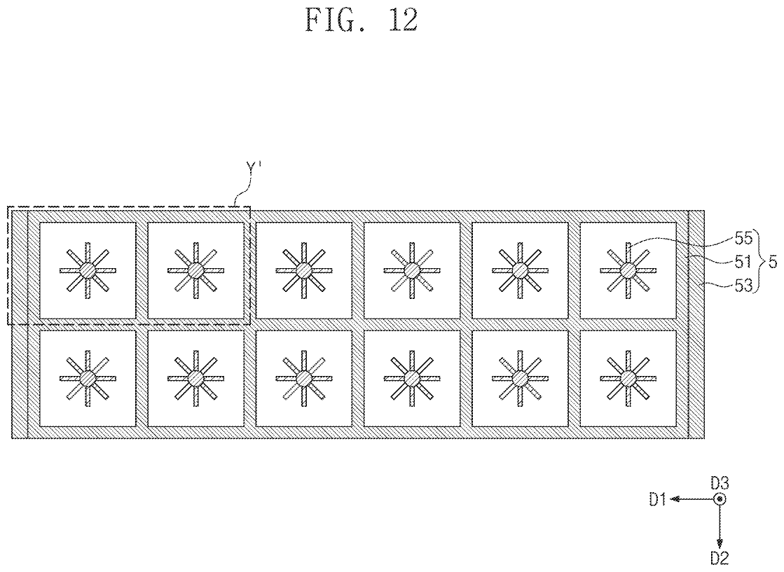

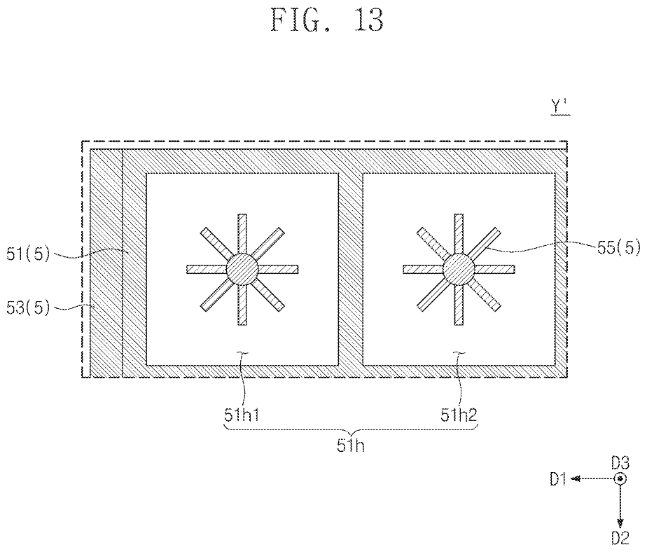

FIG. 10 illustrates a cross-sectional view showing a semiconductor apparatus according to some implementations of the present disclosure. FIG. 11 illustrates an enlarged cross-sectional view showing section X′ of FIG. 10. FIG. 12 illustrates a plan view showing a heat radiation device of a semiconductor apparatus according to some implementations of the present disclosure. FIG. 13 illustrates an enlarged plan view showing section Y′ of FIG. 12.

The following will omit a description of components the same as or similar to those discussed with reference to FIGS. 1 to 9; components illustrated in FIGS. 10-13 can have the same characteristics as the corresponding components of FIGS. 1-9, except where indicated otherwise.

Referring to FIGS. 10 to 13, a semiconductor apparatus SD′ is provided. The semiconductor apparatus SD′ may include a substrate 1, a semiconductor device 3, a heat radiation device 5, an adhesion layer 4, and an edge adhesion layer 2. The heat radiation device 5 may include a radiation plate 51, a support member 53, and a support structure 55.

The radiation plate 51 may provide a plurality of vapor chambers 51h. The radiation plate 51 may not provide a heat pipe channel. For example, different from that discussed with reference to FIGS. 1 to 8, the semiconductor apparatus SD′ of FIGS. 10 to 13 may not provide a heat pipe channel.

According to a heat radiation device and a semiconductor apparatus including the same in accordance with the present disclosure, heat generated from a semiconductor device may be effectively discharged.

According to a heat radiation device and a semiconductor apparatus including the same in accordance with the present disclosure, heat transfer may be prevented between a plurality of semiconductor devices.

According to a heat radiation device and a semiconductor apparatus including the same in accordance with the present disclosure, mechanical stability may be secured.

Benefits that may be provided by implementations of the present disclosure are not limited to the mentioned above, other effects which have not been mentioned above will be clearly understood to those skilled in the art from the following description.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

Although the present disclosure has been described in connection with some implementations according to the present disclosure illustrated in the accompanying drawings, it will be understood to those skilled in the art that various changes and modifications may be made without departing from the technical spirit and essential feature of the present disclosure. It therefore will be understood that the implementations described above are just illustrative but not limitative in all aspects.

What is claimed is:

1. A semiconductor apparatus, comprising:
a substrate;
a plurality of semiconductor devices on the substrate and arranged along a horizontal direction; and
a heat radiation device on the plurality of semiconductor devices,
wherein the heat radiation device includes a plurality of vapor chambers, and
wherein the plurality of vapor chambers are spaced apart from one another in the horizontal direction and are disconnected from one another.

2. The semiconductor apparatus of claim 1, wherein a number of the plurality of vapor chambers is the same as a number of the plurality of semiconductor devices.

3. The semiconductor apparatus of claim 1, wherein the plurality of semiconductor devices include a first semiconductor device and a second semiconductor device,
wherein, when viewed in a plan view, a first one of the plurality of vapor chambers overlaps the first semiconductor device and is non-overlapping with the second semiconductor device.

4. The semiconductor apparatus of claim 1, wherein the heat radiation device includes a support structure in a first vapor chamber of the plurality of vapor chambers,
wherein the support structure includes a support pillar, and
wherein a thickness of the support pillar is the same as a thickness of the first vapor chamber.

5. The semiconductor apparatus of claim 4, wherein the support structure includes a plurality of support plates coupled to the support pillar, and
wherein the plurality of support plates are spaced apart from one another circumferentially around the support pillar.

6. The semiconductor apparatus of claim 4, wherein, when viewed in a plan view, the support pillar is at a center of the first vapor chamber.

7. The semiconductor apparatus of claim 1, comprising an adhesion layer between the heat radiation device and each of the plurality of semiconductor devices,
wherein the adhesion layer is in contact with an entirety of a top surface of a first semiconductor device of the plurality of semiconductor devices.

8. The semiconductor apparatus of claim 1, wherein the horizontal direction is a first horizontal direction, and wherein the heat radiation device includes a first heat pipe channel between two neighboring ones of the plurality of vapor chambers, the first heat pipe channel extending in a second horizontal direction that intersects the first horizontal direction.

9. The semiconductor apparatus of claim 8, wherein the plurality of vapor chambers include:
a first row including a first plurality of vapor chambers arranged in the first horizontal direction; and
a second row including a second plurality of vapor chambers arranged in the first horizontal direction, wherein the second row is spaced apart from the first row in the second horizontal direction.

10. The semiconductor apparatus of claim 9, wherein the heat radiation device comprises a second heat pipe channel between the first row and the second row,
wherein the first heat pipe channel is connected to the second heat pipe channel.

11. A semiconductor apparatus, comprising:
a substrate;
a plurality of semiconductor devices on the substrate; and
a heat radiation device on the plurality of semiconductor devices,
wherein the plurality of semiconductor devices are spaced apart from each other in a first horizontal direction, and
wherein the heat radiation device includes
a plurality of vapor chambers arranged along the first horizontal direction; and
a heat pipe channel between two neighboring ones of the plurality of vapor chambers, the heat pipe channel extending in a second horizontal direction that intersects the first horizontal direction.

12. The semiconductor apparatus of claim 11, wherein
each of the plurality of vapor chambers is disconnected from the heat pipe channel, and
each of the plurality of vapor chambers is separated from the heat pipe channel.

13. The semiconductor apparatus of claim 11, wherein a width in the first horizontal direction of each of the plurality of vapor chambers is greater than a width in the first horizontal direction of the heat pipe channel.

14. The semiconductor apparatus of claim 11, wherein a thickness of each of the plurality of vapor chambers is constant across each of the plurality of vapor chambers in the first horizontal direction.

15. The semiconductor apparatus of claim 11, comprising an edge adhesion layer at an edge of the substrate,
wherein a top surface of the edge adhesion layer is in contact with the heat radiation device.

16. A heat radiation device, comprising:
a radiation plate; and
a support structure coupled to the radiation plate,
wherein the radiation plate defines
a first vapor chamber surrounded by the radiation plate, and
a second vapor chamber surrounded by the radiation plate and spaced apart in a horizontal direction from the first vapor chamber,
wherein the support structure includes:
a support pillar that extends from a first floor surface of the radiation plate to a first ceiling surface of the radiation plate, the first floor surface and the first ceiling surface defining the first vapor chamber; and
a plurality of support plates that extend from the first floor surface to the first ceiling surface and that are coupled to the support pillar,
wherein the plurality of support plates are spaced apart from one another circumferentially around the support pillar.

17. The heat radiation device of claim 16, wherein the radiation plate defines a heat pipe channel between the first vapor chamber and the second vapor chamber,
wherein the heat pipe channel is spaced apart from each of the first vapor chamber and the second vapor chamber and is disconnected from the first vapor chamber and the second vapor chamber.

18. The heat radiation device of claim 16, further comprising a support member that extends downward from an edge of the radiation plate,
wherein a bottom surface of the support member is at a level lower than a level of a bottom surface of the radiation plate.

19. The heat radiation device of claim 16, wherein
a thickness of the radiation plate is in a range of about 3 mm to about 5 mm, and
a thickness of the first vapor chamber is in a range of about 0.3 mm to about 1.5 mm.

20. The heat radiation device of claim 16, further comprising a vapor in the first vapor chamber.
